(19) United States
(12) Patent Application Publication
(10) Pub. No.: US 2025/0208501 A1
(43) Pub. Date: Jun. 26, 2025

(54) SHAPING APPARATUS, SHAPING METHOD, AND ARTICLE MANUFACTURING METHOD

(71) Applicant: CANON KABUSHIKI KAISHA, Tokyo (JP)

(72) Inventor: RYOSUKE TSUTSUMI, Tochigi (JP)

(21) Appl. No.: 18/983,561

(22) Filed: Dec. 17, 2024

(30) Foreign Application Priority Data
Dec. 20, 2023 (JP) 2023-215046

(51) Int. Cl. G03F 7/00

(52) U.S. Cl. CPC G03F 7/0002

(57) ABSTRACT

The present invention provides a shaping apparatus comprising: a film forming device including a holding member to hold a mold, and configured to form a composition between the mold and a substrate by performing a process of driving the holding member holding the mold to bring the mold into contact with the composition on the substrate and then releasing holding of the mold by the holding member; and a curing device configured to cure the composition formed by the film forming device, wherein, after the process, the film forming device performs a press operation of pressing the mold by a member that comes into partial contact with the mold.

### BACKGROUND OF THE INVENTION

### Field of the Invention

The present invention relates to a shaping apparatus, a shaping method, and an article manufacturing method.

### Description of the Related Art

A manufacturing step for a semiconductor device or the like includes a step of etching a substrate using, as a mask, the cured film of a composition with a concave-convex pattern formed on the substrate. At this time, if the residual film thickness of the concave-convex pattern in the cured film formed on the substrate (the thickness of the cured film between the concave portion of the concave-convex pattern and the substrate) is not uniform over the entire area of the substrate, it can be difficult to accurately control the etching. Hence, a planarization technique for forming a planarized film (that is, a film having a flat surface) on a substrate is required.

As one of planarization techniques, a technique of planarizing a composition on a substrate by shaping the composition on the substrate using a mold having a flat surface is known. More specifically, it is possible to planarize a composition on a substrate by curing the composition while the flat surface of a mold is in contact with the composition on the substrate and then separating the mold from the cured composition. The mold used for such a planarization technique is sometimes called a superstrate or a planar template.

In the planarization technique, in order to form the liquid film of a composition having a uniform thickness between a mold and a substrate by letting the surface shape of the mold conform to the concave and convex (unevenness) of the substrate surface due to the surface tension of the composition spreading between the mold and the substrate, the mold preferably has a thickness as small as possible (for example, about 200 μm). However, in practice, from the viewpoint of ease of handling the mold in replacement and conveyance of the mold, the mold has a certain degree of thickness (for example, about 500 μm to 800 μm). In this case, since the rigidity of the mold increases as the thickness of the mold increases, it can be difficult to form the liquid film of the composition having a uniform thickness between the mold and the substrate by letting the surface shape of the mold conform to the concave and convex of the substrate surface only by utilizing the surface tension of the composition. Accordingly, in order to accurately form the liquid film of the composition between the mold and the substrate, it is necessary to apply an external force to the mold. Japanese Patent Laid-Open No. 2022-41583 proposes a method of applying an external force to a mold by blowing a gas to the mold in contact with the composition on a substrate, but a method of more efficiently applying an external force to a mold is desired.

### SUMMARY OF THE INVENTION

The present invention provides, for example, a technique advantageous in accurately forming the liquid film of a composition between a mold and a substrate.

According to one aspect of the present invention, there is provided a shaping apparatus comprising: a film forming device including a holding member to hold a mold, and configured to form a composition between the mold and a substrate by performing a process of driving the holding member holding the mold to bring the mold into contact with the composition on the substrate and then releasing holding of the mold by the holding member; and a curing device configured to cure the composition formed by the film forming device, wherein, after the process, the film forming device performs a press operation of pressing the mold by a member that comes into partial contact with the mold.

Further features of the present invention will become apparent from the following description of exemplary embodiments with reference to the attached drawings.

### BRIEF DESCRIPTION OF THE DRAWINGS

FIG. 1 is a schematic view showing an arrangement example of a planarization apparatus (shaping apparatus);

FIGS. 2A to 2D are views for explaining a planarization process of the first embodiment;

FIGS. 3A and 3B are views each for explaining the state of the liquid film of a composition between a superstrate and a substrate;

FIG. 4 is a flowchart illustrating the planarization process including a press operation;

FIGS. 5A and 5B are views each showing an arrangement example of a pressing member; and

FIGS. 6A to 6C are views for explaining a planarization process of the second embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate.

Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate (or a holding surface for holding a substrate) are defined as the X-Y plane, unless otherwise specified. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are OX, OY, and OZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the OX-axis, the OY-axis, and the OZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes.

A shaping apparatus is an apparatus that performs a shaping process of shaping a composition on a substrate by pressing a mold against the composition. Examples of the shaping apparatus are an imprint apparatus and a planarization apparatus. The imprint apparatus is an apparatus that brings a mold including a concave-convex pattern into contact with a composition (imprint material) on a substrate to form (transfer) the pattern on the composition. The shaping process performed by the imprint apparatus is sometimes called an imprint process. The planarization apparatus is an apparatus that planarizes the surface of a composition by bringing a mold having a flat surface into contact with the composition on a substrate. The shaping process performed by the planarization apparatus is sometimes called a planarization process.

### First Embodiment

A shaping apparatus of the first embodiment according to the present invention will be described. In this embodiment, a planarization apparatus will be exemplified as the shaping apparatus, but arrangement/process of the planarization apparatus can also be applied to the imprint apparatus. The planarization apparatus is a lithography apparatus that planarizes (shapes) a composition on a substrate using a mold, and can be employing in a lithography step that is a manufacturing step for a semiconductor device, a magnetic storage medium, or the like. The mold used in the planarization apparatus has a flat surface as a shaping surface (contact surface) which is brought into contact with a composition on a substrate and shapes the composition. The mold is sometimes called a superstrate or a planar template. Hereinafter, a mold having a flat surface is sometimes referred to as a “superstrate”.

The underlying pattern on a substrate has a concave-convex height difference due to the pattern formed in the preceding step. If the height difference is large, it may fall outside the Depth Of Focus (DOF) of an exposure apparatus used in the succeeding step. Conventionally, as a method for smoothing the underlying pattern on a substrate, a method of forming a planarized layer, such as Spin On Carbon (SOC) or Chemical Mechanical Polishing (CMP), is used. However, the concave-convex height difference of the underlying pattern caused by multilayered structure tends to increase year by year, and there is a problem that the conventional technique cannot achieve sufficient planarization performance. To solve this problem, the planarization apparatus of this embodiment planarizes a composition on a substrate using a superstrate having a flat surface. More specifically, the planarization apparatus cures the composition while the flat surface of the superstrate is in contact with the composition supplied onto the substrate, and then separates the superstrate from the cured composition. Thus, a planarized film (planarized layer) made of the cured product of the composition can be formed on the substrate.

As the composition, a curable composition (to be also referred to a resin in an uncured state) that is cured by receiving curing energy is used. As the curing energy, an electromagnetic wave, heat, or the like is used. As the electromagnetic waves, for example, infrared light, visible light, ultraviolet light, and the like selected from the wavelength range of 10 nm (inclusive) to 1 mm (inclusive) is used. The curable composition can be a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like. The composition can be arranged on the substrate in a droplet shape or in an island or film shape formed by connecting a plurality of droplets using a composition supply apparatus (a supply device 20 to be described later). For example, the composition dropped onto the substrate can be arranged on the substrate as hemispherical droplets each having a diameter of about 10 μm to 20 μm with a minute volume. The viscosity (the viscosity at 25° C.) of the composition can be, for example, 1 mPa·s (inclusive) to 100 mPa·s (inclusive).

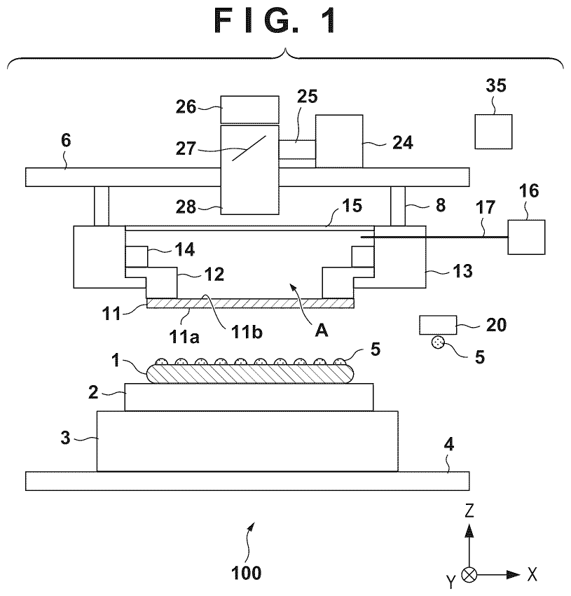

FIG. 1 is a schematic view showing an arrangement example of a planarization apparatus 100 (shaping apparatus) of this embodiment. In FIG. 1, a substrate 1 is loaded into the planarization apparatus 100 by a substrate conveyance device (not shown) including a conveyance hand or the like, and held by a substrate chuck 2 serving as a substrate holder. A substrate stage 3 is configured to be movable on a base plate 4, and drives the substrate 1 in the X and Y directions by driving the substrate chuck 2 to position the substrate 1 held by the substrate chuck 2 at a predetermined position. As the material of the substrate 1, for example, glass, ceramic, a metal, a semiconductor, a resin, or the like is used. A member made of a material different from that of the substrate 1 may be provided on the surface of the substrate 1, as needed. The substrate 1 includes, for example, a silicon wafer, a semiconductor compound wafer, or silica glass. The substrate 1 includes a concave-convex structure due to the pattern formed in the preceding step. The planarization apparatus 100 can be used to form, on the substrate, a planarized film covering the concave-convex structure.

A superstrate 11 (mold) can be made of a material (such as silica glass) that transmits light. The shape of the superstrate 11 has, for example, a circular outer shape when viewed from the +Z direction. The shaping surface (first surface) to be brought into contact with a composition 5 on the substrate 1 to shape the composition 5 is a flat surface 11a. When the flat surface 11a of the superstrate 11 contacts the composition 5 on the substrate 1, the superstrate 11 can be deformed to conform to the surface shape (the concave-convex shape viewed in the X direction or the Y direction) of the substrate 1 due to the surface tension of the composition 5. The outer diameter of the superstrate 11 matches, for example, the outer diameter of the substrate 1. The superstrate 11 is loaded into the planarization apparatus 100 by a mold conveyance device (not shown), and held by a holding member 12 (mold holder or mold chuck). The holding member 12 holds the superstrate 11 by contacting the outer peripheral portion of a back surface 11b (the surface (second surface) on the opposite side of the flat surface 11a) of the superstrate 11 and attracting the outer peripheral portion. The holding member 12 can hold the superstrate 11 by, for example, vacuum-sucking the outer peripheral portion of the superstrate 11.

The holding member 12 is supported by a head 13. The head 13 can include a driving mechanism that drives the superstrate 11 by driving the holding member 12. For example, the head 13 drives the superstrate 11 in the Z-axis direction to bring the superstrate 11 into contact with the composition 5 on the substrate 1 or separate the superstrate 11 from the cured composition 5. The head 13 may have a function for correcting the tilt of the superstrate 11. The driving mechanism of the head 13 can be formed from, for example, an actuator such as a linear motor, an air cylinder, or a voice coil motor. The head 13 is fixed to guide bars 8 suspended from a bridge structure 6. The bridge structure 6 is supported by supports (not shown) fixed to the base plate 4.

Here, the holding member 12 is supported by the head 13 such that it can tilt relative to the head 13 in accordance with the shape of the back surface 11b in a state in which its holding surface (the surface for holding the superstrate 11) is in contact with the back surface 11b of the superstrate 11. That is, the holding member 12 has the flexibility that allows it to tilt in accordance with the shape of the superstrate 11. For example, if an external force is applied to the superstrate 11 held by the holding member 12 so that the entire superstrate 11 is bent and deformed into a downward convex shape, the holding member 12 tilts such that the holding surface faces outward. With this, the shape of the superstrate 11 can be maintained as a quadratic curved surface corresponding to the downward convex shape. On the other hand, if the entire superstrate 11 is bent and deformed into an upward convex shape, the holding member 12 tilts such that the holding surface faces inward. With this, the shape of the superstrate 11 can be maintained as a quadratic curved surface corresponding to an upward convex shape.

A force detector 14 (second detector) that detects the pressing force applied to the superstrate 11 by the holding member 12 is provided in the head 13. The force detector 14 may be understood as a detector that detects the external force transmitted to the holding member 12 via the superstrate 11. As the force detector 14, for example, a strain gauge type load sensor, or a load sensor (load cell) that detects the force from the current value applied to the driving mechanism (actuator) of the head 13 can be used. Note that, in FIG. 1, the force detector 14 is shown as a structure different from the head 13 and the holding member 12, but the force detector 14 may be included in the head 13 or the holding member 12.

Furthermore, a flat plate optical element 15, which is formed by a light transmissive member such as silica glass, is provided in the head 13. The flat plate optical element 15 is attached to the head 13 so as to form a spatial region A as a closed space between the superstrate 11 and the flat plate optical element 15. That is, the flat plate optical element 15 functions as a seal member for closing the spatial region A. The internal pressure of the spatial region A can be adjusted (controlled) by a pressure adjustment device 16 via a pipe 17. For example, the pressure adjustment device 16 makes the internal pressure of the spatial region A higher than atmospheric pressure, thereby deforming the superstrate 11 into a downward convex shape and gradually bringing the superstrate 11 into contact with the composition 5 on the substrate 1 from the central portion of the superstrate 11. This can reduce confinement of bubbles between the superstrate 11 and the substrate 1.

In the planarization process, a curing device 24 irradiates, with light (for example, ultraviolet light), the liquid film of the composition 5 formed between the superstrate 11 and the substrate 1, thereby curing the composition 5. The curing device 24 in this embodiment includes a light source formed from a UV lamp or a UV LED. The light emitted from the curing device 24 passes through a light path tube 25 including a collimator lens (not shown), and is reflected by a mirror 27 and emitted from an opening portion 28, thereby irradiating the composition 5 on the substrate 1 via the superstrate 11.

Here, if the superstrate 11 has the same shape and size as the substrate 1, in a state in which the superstrate 11 is held by the holding member 12, light irradiation to the region of the surface of the substrate 1 facing the holding member 12 is blocked by the holding member 12. That is, the composition 5 on this region of the surface of the substrate 1 can be cured insufficiently. To prevent this, the planarization apparatus 100 of this embodiment brings the superstrate 11 into contact with the composition 5 on the substrate 1 to form the liquid film of the composition 5 between the superstrate 11 and the substrate 1 and, after that, releases holding of the superstrate 11 by the holding member 12. Then, the head 13 lifts the holding member 12 to separate the holding member 12 from the superstrate 11. In this state, the curing device 24 irradiates, with light, the liquid film of the composition 5 between the superstrate 11 and the substrate 1. This prevents the holding member 12 from blocking the light from the curing device 24, so that the light irradiation region on the substrate 1 can be increased and the composition 5 can be cured in the entire area of the substrate 1.

A spread camera 26 (contact detector) is a camera for detecting (observing) the contact state between the superstrate 11 and the composition 5 on the substrate 1, that is, the state of the liquid film of the composition 5 formed between the superstrate 11 and the substrate 1. The spread camera 26 can also be used as an abnormality detector (first detector) that detects an abnormal portion with a nonuniform thickness in the liquid film of the composition 5 formed between the superstrate 11 and the substrate 1. The spread camera 26 includes, for example, a wide angle lens. In this case, the field of view of the camera is not limited to the size of the opening portion 28, and the spread camera 26 has a wide field of view (angle of view) that enables detection (observation) of the entire region of the substrate 1. Here, when detecting the contact state between the superstrate 11 and the composition 5 on the substrate 1 by the spread camera 26, the mirror 27 can be retracted from the field of view of the spread camera 26. However, the present invention is not limited to this, and the mirror 27 may be formed by a half mirror that reflects light from the curing device 24 but transmits light to the spread camera 26.

The supply device 20 supplies the composition 5 onto the substrate 1. The supply device 20 in this embodiment is formed from a dispenser including discharge outlets (nozzles) for discharging the composition 5 (the resin in an uncured state) onto the substrate 1. For example, the supply device 20 employs a piezoelectric jet method, a micro solenoid method, or the like, and is configured to discharge the composition 5 as a plurality of droplets each has a minute volume of about 1 μL (picoliter). When the supply device 20 discharges the composition 5 as a plurality of droplets while the substrate stage 3 moves the substrate 1 in the X and Y directions below the supply device 20, the composition 5 can be supplied as the plurality of droplets onto the entire area of the substrate 1.

A controller 35 is formed from a computer (information processing apparatus) including a processor such as a Central Processing Unit (CPU) and a storage such as a memory. The controller 35 is connected to respective units of the planarization apparatus 100 by lines, and controls the planarization process by comprehensively controlling the respective units of the planarization apparatus 100. The planarization process is a process of bringing the flat surface 11a of the superstrate 11 into contact with the composition 5 on the substrate 1 and letting the flat surface 11a conform to the surface shape of the substrate 1, thereby planarizing the composition 5 on the substrate 1. In addition, in this embodiment, the controller 35 can determine, based on image information obtained from the spread camera 26, the contact state between the superstrate 11 and the composition 5 on the substrate 1. Furthermore, the controller 35 can specify (detect) an abnormal portion with a nonuniform thickness in the liquid film of the composition 5 formed between the superstrate 11 and the substrate 1 based on image information obtained from the spread camera 26. Note that the controller 35 may be formed from a PLD (an abbreviation of Programmable Logic Device) such as an FPGA (an abbreviation of Field Programmable Gate Array), or an ASIC (an abbreviation of Application Specific Integrated Circuit).

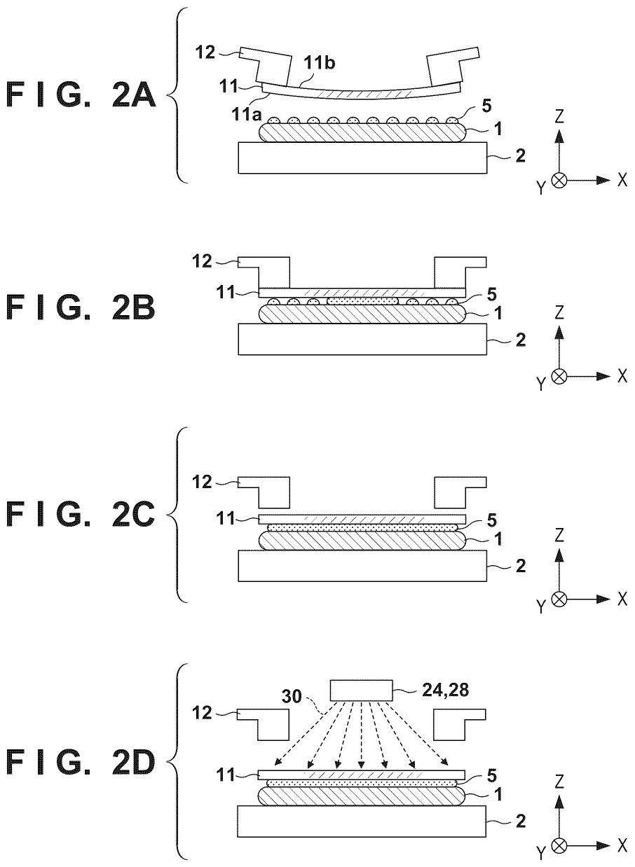

Next, the planarization process will be described with reference to FIGS. 2A to 2D. FIGS. 2A to 2D are views for explaining the planarization process. FIGS. 2A to 2D show only the elements necessary for explanation of the planarization process, and illustration of other elements is omitted.

FIG. 2A shows a state before the superstrate 11 is brought into contact with the composition 5 on the substrate 1. In FIG. 2A, the composition 5 supplied as the plurality of droplets by the supply device 20 is arranged on the substrate 1. The droplets of the composition 5 are arranged on the substrate 1 while being separated from each other. The supply pattern (arrangement pattern) of the droplets of the composition 5 on the substrate 1 can be decided in advance based on the steps of the underlying pattern or the like formed on the surface of the substrate 1. However, the actual substrate 1 includes not only the steps of the underlying pattern but also the concave and convex of the substrate 1 itself. Hence, the supply pattern may be decided based on the steps of the underlying pattern and the concave and convex of the substrate 1 itself.

When bringing the superstrate 11 into contact with the composition 5 on the substrate 1, in order to reduce confinement of bubbles between the superstrate 11 and the substrate 1, the central portion of the superstrate 11 is preferably deformed into a convex shape projecting toward the substrate 1. More specifically, the pressure adjustment device 16 increases the internal pressure of the spatial region A as the closed space, and this can deform the superstrate 11 into a convex shape as shown in FIG. 2A. At this time, the holding member 12 tilts such that its holding surface faces outward. With this, the flat surface 11a of the superstrate 11 becomes a quadratic curved surface, and the shape of the central portion of the flat surface 11a becomes closest to that of the substrate 1.

FIG. 2B shows a state immediately after the superstrate 11 contacts the composition 5 on the substrate 1. For example, in the state in which the internal pressure of the spatial region A is increased by the pressure adjustment device 16 and the flat surface 11a of the superstrate 11 is deformed into the convex shape, the head 13 lowers the superstrate 11 (holding member 12). With this, the contact between the flat surface 11a of the superstrate 11 and the composition 5 on the substrate 1 can be started from the central portion of the superstrate 11. Thereafter, the pressure adjustment device 16 decreases the internal pressure of the spatial region A to return the flat surface 11a of the superstrate 11 to the planar shape. Thus, the composition 5 on the substrate 1 spreads outwardly of the substrate 1 along the flat surface 11a of the superstrate 11.

Here, while the superstrate 11 is held by the holding member 12, the effect of this holding prevents the superstrate 11 from conforming to the surface shape of the substrate 1, making it difficult to form a continuous liquid film of the composition 5 between the superstrate 11 and the substrate 1. Therefore, as will be described later with reference to FIG. 2C, holding of the superstrate 11 by the holding member 12 is released in the planarization process. Note that the phrase “it is difficult to form a continuous liquid film of the composition 5” means, for example, that a portion where the composition 5 remains as droplets and/or a portion with a nonuniform thickness can exist between the superstrate 11 and the substrate 1.

FIG. 2C shows a state in which holding of the superstrate 11 by the holding member 12 is released. When holding of the superstrate 11 by the holding member 12 is released, the pressure due to the mass of the superstrate 11 is evenly applied to the composition 5 (including its outer peripheral portion) on the substrate 1. This can let the superstrate 11 conform to the surface shape of the substrate 1, and the liquid film of the composition 5 is formed between the superstrate 11 and the substrate 1. Here, for distinguishment from the state shown in FIG. 2B, FIG. 2C shows the state in which the superstrate 11 is separated from the holding member 12. However, as long as holding of the superstrate 11 by the holding member 12 is released, the liquid film of the composition 5 can be formed between the superstrate 11 and the substrate 1 without separating the holding member 12 from the superstrate 11. In a case where the holding member 12 is configured to hold the superstrate 11 by vacuum suction, a release of holding of the superstrate by the holding member 12 may be understood to be a stop of vacuum suction of the superstrate 11 by the holding member 12. Also in this case, as long as vacuum suction of the superstrate 11 by the holding member 12 is stopped, the holding member 12 may not be separated from the superstrate 11.

In this manner, in the planarization process, after the head 13 drives the holding member 12 to bring the superstrate 11 into contact with the composition 5 on the substrate 1, holding of the superstrate 11 by the holding member 12 is released. Through this process, the liquid film of the composition 5 can be formed between the superstrate 11 and the substrate 1. Hence, the holding member 12 and the head 13 (driving mechanism) may be understood to form a film forming device that forms the liquid film of the composition 5 between the superstrate 11 and the substrate 1.

FIG. 2D shows a state in which the liquid film of the composition 5 formed between the superstrate 11 and the substrate 1 is cured. More specifically, the head 13 lifts the holding member 12 to separate the holding member 12 from the superstrate 11 so that the portion of the liquid film of the composition 5 between the superstrate 11 and the substrate 1, which is located below the holding member 12, is also irradiated with light 30 from the curing device 24. In this state, the curing device 24 emits the light 30, and the light 30 is applied to the liquid film of the composition 5 via the superstrate 11, thereby curing the composition 5 between the superstrate 11 and the substrate 1. Here, if the light 30 from the curing device 24 is not sufficiently applied over the entire liquid film of the composition 5, that is, if the end portion of the substrate 1 is not irradiated with the light 30, the substrate stage 3 may be moved in the X and Y directions to allow the end portion of the substrate 1 to be irradiated with the light 30.

After the composition 5 is cured, the head 13 lowers the holding member 12 to bring the holding member 12 into contact with the superstrate 11, thereby causing the holding member 12 to hold the superstrate 11. Then, the head 13 lifts the holding member 12, thereby separating the superstrate 11 held by the holding member 12 from the cured composition 5. Thus, a planarized film (planarized layer) made of the cured product of the composition 5 can be formed in the entire area of the substrate 1.

In order to form the liquid film of the composition 5 having a uniform thickness between the superstrate 11 and the substrate 1 by letting the flat surface 11a of the superstrate 11 conform to the surface shape of the substrate 1 due to the surface tension of the composition 5, the superstrate 11 preferably has a small thickness. However, in practice, from the viewpoint of ease of handling of the superstrate 11 in replacement and conveyance of the superstrate 11, the superstrate 11 has a certain degree of thickness. In this case, since the rigidity of the superstrate 11 increases as the thickness of the superstrate 11 increases, it can be difficult to let the flat surface 11a of the superstrate 11 conform to the surface shape of the substrate 1 only by utilizing the surface tension of the composition 5.

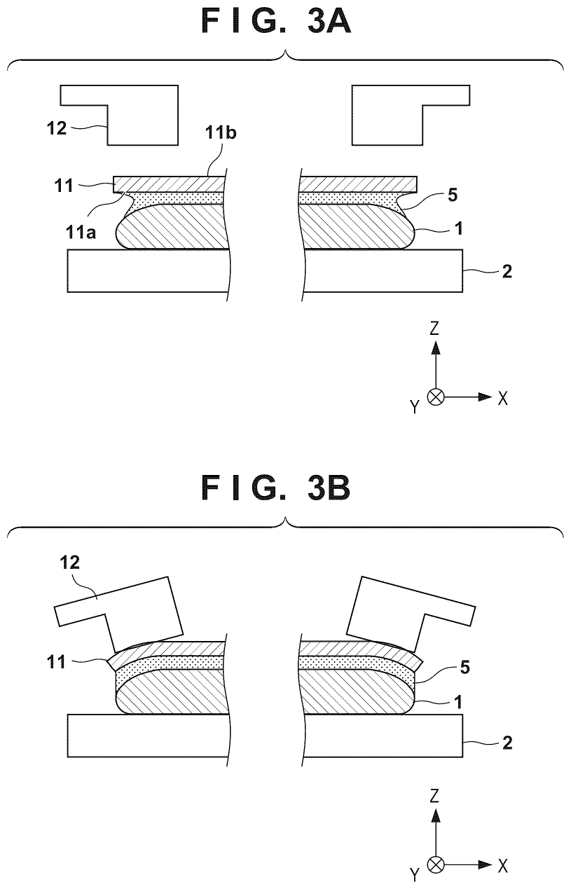

For example, due to the processing step (polishing) of the substrate 1, a portion (to be sometimes referred to as edge roll-off or sagging) thinner than the central portion of the substrate 1 can be generated in the outer peripheral portion (end portion or peripheral portion) of the substrate 1. Alternatively, the outer peripheral portion of the substrate 1 may be chamfered. In addition, in the outer peripheral portion of the substrate 1, the flatness may be decreased due to warping of the substrate 1 caused by the succeeding step (baking) performed after the underlying pattern is formed on the substrate 1. In this manner, in the region such as the outer peripheral portion of the substrate 1 where the degree of decrease in flatness is large, the superstrate 11 cannot sufficiently conform to the surface shape of the substrate 1 due to the surface tension of the composition 5, as shown in FIG. 3A. As a result, it can be difficult to form the liquid film of the composition 5 having a uniform thickness between the superstrate 11 and the substrate 1. FIG. 3A is an enlarged view showing portions (both end portions) of FIG. 2C, and shows a state in which the liquid film of the composition 5 is formed between the superstrate 11 and the substrate 1.

To solve this problem, in order to decrease the nonuniformity of the liquid film of the composition 5, the planarization apparatus 100 of this embodiment performs a press operation of partially pressing the back surface 11b of the superstrate 11 by a member that comes into partial contact with the back surface 11b of the superstrate 11. The press operation is performed after holding of the superstrate by the holding member 12 is released as shown in FIG. 2C and before the composition 5 is cured as shown in FIG. 2D. With this, the liquid film of the composition 5 having a uniform thickness can be formed between the superstrate 11 and the substrate 1. An example will be described below in which the press operation is performed using the holding member 12 as the “member that comes into partial contact with the back surface 11b of the superstrate 11”.

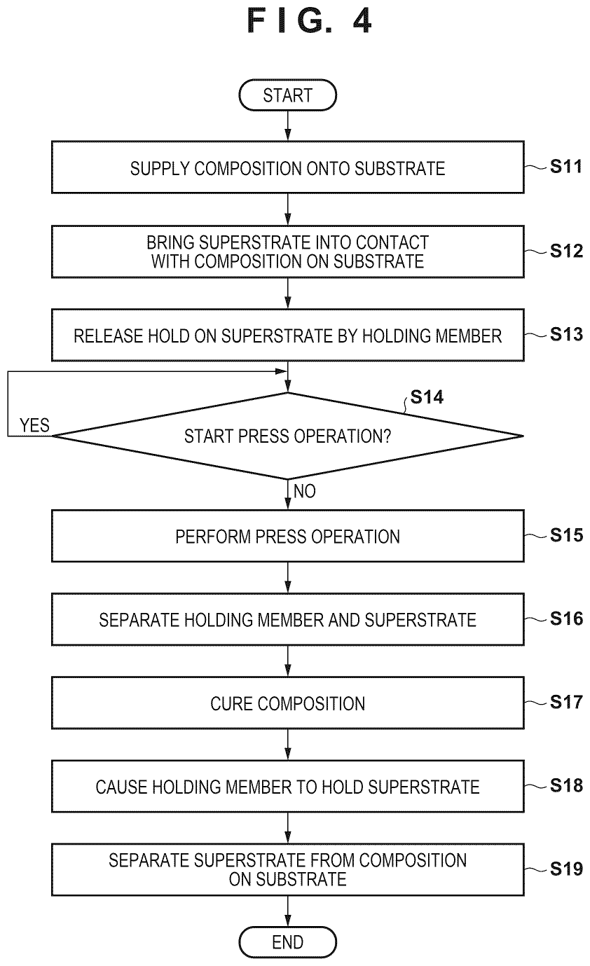

FIG. 4 is a flowchart illustrating a planarization process (shaping method) of this embodiment including the press operation. The flowchart of FIG. 4 can be executed by the controller 35.

In step S11, the controller 35 causes the supply device 20 to supply the composition 5 as a plurality of droplets onto the substrate 1. For example, as has been described above, the controller 35 can supply the composition 5 as the plurality of droplets onto the substrate 1 by causing the supply device 20 to discharge the composition 5 as the plurality of droplets while moving the substrate 1 below the supply device 20.

In step S12, the controller 35 causes the head 13 to lower the holding member 12 holding the superstrate 11, thereby bringing the superstrate 11 into contact with the composition 5 on the substrate 1. This step S12 is as described above using FIGS. 2A and 2B, so that a detailed description here will be omitted. Then, in step S13, the controller 35 releases holding of the superstrate 11 by the holding member 12. This step S13 is as described above using FIG. 2C, so that a detailed description here will be omitted. In step S13, after holding of the superstrate 11 by the holding member 12 is released, the head 13 may lift the holding member 12 to separate the holding member 12 from the superstrate 11.

In step S14, the controller 35 determines whether to start the press operation. For example, the controller 35 can decide the start timing of the press operation based on image information obtained from the spread camera 26. As has been described using FIG. 2B, the contact between the superstrate 11 and the composition 5 on the substrate 1 is started from the central portion of the superstrate 11. Then, the composition 5 supplied (arranged) as the plurality of droplets on the substrate 1 spreads outwardly of the substrate 1 between the superstrate 11 and the substrate 1 while the adjacent droplets of the composition 5 connect to each other, and changes to a liquid film. Therefore, if the press operation is started before the composition 5 spreads over the entire area of the substrate 1, the press operation hinders connection of the droplets of the composition 5, and this can result in a noncontinuous liquid film of the composition 5 between the superstrate 11 and the substrate 1. To prevent this, the controller 35 preferably determines, based on image information obtained from the spread camera 26, to start the press operation if the composition 5 spreads over the entire area of the substrate 1. If it is determined to start the press operation, the process advances to step S15. Note that, at the time when holding of the superstrate 11 by the holding member 12 is released in step S13, the composition 5 may have spread over the entire area of the substrate 1. In this case, step S14 may be omitted, and the press operation may be started simultaneously with the release of holding (the stop of vacuum suction) by the holding member 12.

In step S15, the controller 35 performs the press operation of partially pressing the back surface 11b of the superstrate 11. More specifically, if the holding member 12 and the superstrate 11 are separated, the controller 35 causes the head 13 to lower the holding member 12 to bring the holding member 12 into contact with the outer peripheral portion in the back surface 11b of the superstrate 11. Then, as shown in FIG. 3B, in a state in which holding of the superstrate 11 by the holding member 12 is released, that is, in a state in which vacuum suction of the holding member 12 is stopped, the controller 35 causes the head 13 to press the holding member 12 against the back surface 11b of the superstrate 11. That is, the holding member 12 presses the back surface 11b of the superstrate 11.

Here, the controller 35 may control the press operation based on the detection result of the force detector 14 such that the pressing force of the holding member 12 against the superstrate 11 reaches a target pressing force. The thickness of the liquid film of the composition 5 formed between the superstrate 11 and the substrate 1 can change in accordance with the pressing force of the holding member 12 against the superstrate 11. That is, the thickness of the liquid film of the composition 5 tends to decrease as the pressing force increases, and increase as the pressing force decreases. Accordingly, by acquiring, in advance, the relationship between the thickness of the liquid film of the composition 5 and the pressing force by experiment, simulation, or the like, the controller 35 can decide the pressing force corresponding to the target thickness of the liquid film of the composition 5 as a target pressing force (the upper limit value of the pressing force). The controller 35 monitors the detection result of the force detector 14 during the press operation, and ends the press operation when the pressing force detected by the force detector 14 reaches the target pressing force. With this, the liquid film of the composition 5 having a desired uniform thickness can be formed between the superstrate 11 and the substrate 1.

In step S16, the controller 35 causes the head 13 to lift the holding member 12 to separate the holding member 12 from the superstrate 11. Here, since the composition 5 is a viscous liquid (resin), an attractive force occurs between the superstrate 11 and the substrate 1 due to the surface tension of the composition 5. Therefore, even after the holding member 12 is separated from the superstrate 11, the shape of the superstrate 11 is maintained, and the uniform thickness of the liquid film of the composition 5 between the superstrate 11 and the substrate 1 can be maintained.

In step S17, the controller 35 causes the curing device 24 to emit the light 30, thereby irradiating the composition 5 between the superstrate 11 and the substrate 1 with the light 30 to cure the composition 5. This step S17 is as described above using FIG. 2D, so that a detailed description here will be omitted.

In step S18, the controller 35 causes the head 13 to lower the holding member 12, thereby bringing the holding member 12 into contact with the superstrate 11 to hold the superstrate 11 by the holding member 12. Then, in step S19, the controller 35 causes the head 13 to lift the holding member 12 holding the superstrate 11, thereby separating the superstrate 11 from the cured composition 5 on the substrate 1. With this, a planarized film made of the cured product of the composition 5 having a uniform thickness can be formed on the substrate 1.

As has been described above, the planarization apparatus 100 of this embodiment performs the press operation after driving the holding member 12 holding the superstrate 11 to bring the superstrate 11 into contact with the composition on the substrate 1 and releasing holding of the superstrate 11 by the holding member 12. The press operation is an operation of partially pressing the back surface 11b of the superstrate 11 by the holding member 12 so as to decrease the nonuniformity of the liquid film of the composition 5. With this, the liquid film of the composition 5 having a uniform thickness can be formed between the superstrate 11 and the substrate 1. That is, a planarized film made of the cured product of the composition 5 having a uniform thickness can be formed on the substrate 1. As a result, for example, defocusing occurring in an exposure apparatus used in a succeeding step can be reduced, and variations in line width of a pattern to be formed in the substrate in an etching step as a further succeeding step can be reduced.

Here, in this embodiment, the example of pressing the outer peripheral portion of the back surface 11b of the superstrate 11 by the holding member 12 in the press operation has been described. In this case, planarization of the composition 5 in the outer peripheral portion of the superstrate 11, that is, in the outer peripheral portion of the substrate 1 can be improved. However, in the press operation, by moving the substrate stage 3 in the X and Y directions, the holding member 12 may press a portion (for example, central portion) of the back surface 11b of the superstrate 11 other than the outer peripheral portion. In this case, planarization of the composition 5 in this portion can be improved. Further, there can be a method of improving planarization of the composition 5 in the central portion of the substrate 1 by the pressure adjustment device 16 in the press operation. For example, while the holding member 12 presses the back surface 11b of the superstrate 11, the spatial region A is a closed space. Accordingly, while the holding member 12 presses the back surface 11b of the superstrate 11 in the press operation, the pressure adjustment device 16 may increase the internal pressure of the spatial region A. In this case, since the central portion of the back surface 11b of the superstrate 11 is pressed, this has an effect of promoting planarization of the composition 5.

### Second Embodiment

The second embodiment according to the present invention will be described. In the first embodiment described above, the example has been described in which the press operation is performed using the holding member 12. In this embodiment, an example will be described in which a press operation is performed using a member different from the holding member 12. Note that this embodiment basically takes over the first embodiment, and matters not mentioned below can follow the first embodiment.

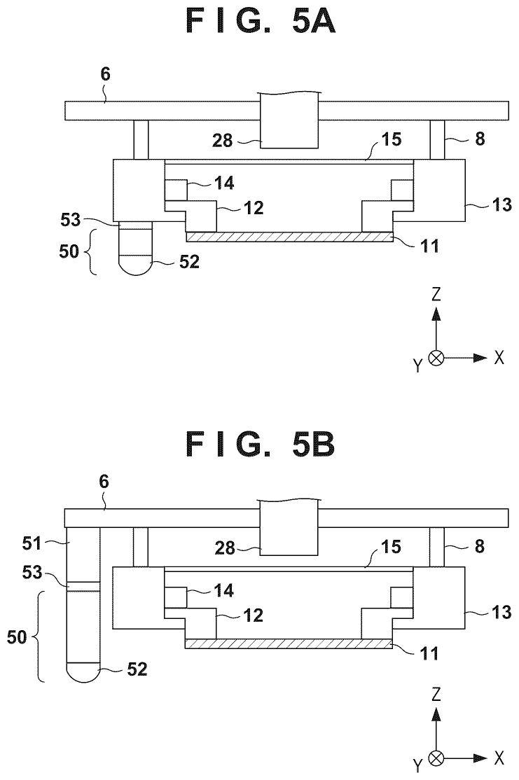

As shown in FIGS. 5A and 5B, a planarization apparatus 100 of this embodiment can further include a pressing member 50 different from a holding member 12 as a “member that partially presses a back surface 11b of a superstrate 11 by partially contacting the back surface 11b”. Each of FIGS. 5A and 5B is a view showing an arrangement example of the pressing member 50, and shows an extracted portion of the planarization apparatus 100 shown in FIG. 1. As shown in FIG. 5A, the pressing member 50 may be configured to be supported by a head 13 and driven in the Z direction by a driving mechanism of the head 13. Alternatively, as shown in FIG. 5B, the pressing member 50 may be configured to be supported by a bridge structure 6 via a driving mechanism 51 and driven in the Z direction by the driving mechanism 51. A distal end portion 52 of the pressing member 50 may be made of an elastic material so as not to damage the back surface 11b of the superstrate 11.

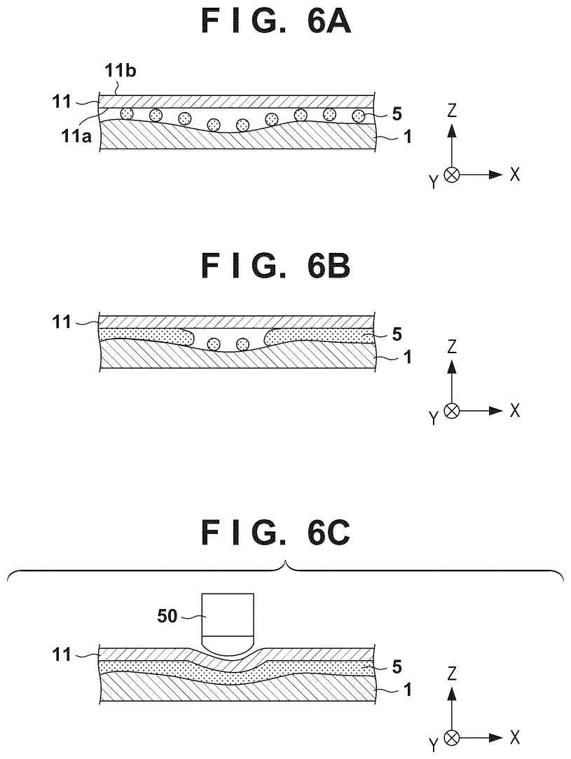

Next, a planarization process of this embodiment will be described with reference to FIGS. 6A to 6C. FIGS. 6A to 6C are views for explaining the planarization process of this embodiment. FIGS. 6A to 6C show only the elements necessary for explanation of the planarization process, and illustration of other elements is omitted.

FIG. 6A shows a state immediately after the superstrate 11 is brought into contact with a composition 5 on a substrate 1. As has been described above, the composition 5 supplied as a plurality of droplets by a supply device 20 is arranged on the substrate 1. The supply pattern (supply amount) of the droplets of the composition 5 on the substrate 1 is decided in advance based on the steps of the underlying pattern or the like formed on the surface (underlayer) of the substrate 1. Even if the substrate 1 itself has concave and convex (undulation), the supply pattern (supply amount) is not changed in accordance with the concave and convex. Therefore, among the concave and convex of the substrate 1 itself, the top end position of the droplet of the composition 5 is high in the convex region, and the top end position of the droplet of the composition 5 is low in the concave region. The contact between the superstrate 11 and the composition 5 on the substrate 1 is started from the central portion of the superstrate 11, but from a local perspective, the higher the top end position of the droplet of the composition 5 in the convex region, the earlier the contact between the superstrate 11 and the composition 5 starts. Similarly, the lower the top end position of the droplet of the composition 5 in the concave region, the later the contact between the superstrate 11 and the composition 5 starts.

FIG. 6B shows a state in which, after the superstrate 11 contacts the composition 5 on the substrate 1, the droplets of the composition 5 connect to each other and the liquid film of the composition 5 is formed between the superstrate 11 and the substrate 1. Among the concave and convex of the substrate 1 itself, in the concave region, the superstrate 11 cannot sufficiently conform to the surface shape of the substrate 1 so that the contact between the superstrate 11 and the composition 5 can be insufficient. If the contact is insufficient, connection of the droplets of the composition 5 is hindered and the droplets of the composition 5 may remain in an unconnected or incompletely connected state. This can result in the noncontinuous liquid film of the composition 5 between the superstrate 11 and the substrate 1. That is, an abnormal portion with a nonuniform thickness can be generated in the liquid film of the composition 5 formed between the superstrate 11 and the substrate 1. Hence, in the planarization apparatus 100 of this embodiment, the press operation is controlled to cause the pressing member 50 to selectively press a part of the superstrate 11 corresponding to the abnormal portion.

For example, after the superstrate 11 starts to contact the composition 5 on the substrate 1, simultaneously with the release of holding of the superstrate 11 by the holding member 12, a spread camera 26 starts detection (observation) of the contact state between the superstrate 11 and the composition 5. The contact state between the superstrate 11 and the composition 5 on the substrate 1 may be understood as the state of the liquid film of the composition 5 formed between the superstrate 11 and the substrate 1, that is, the progress of connection of the droplets of the composition 5 between the superstrate 11 and the substrate 1. With this, based on image information obtained from the spread camera 26, the controller 35 can specify (detect) an abnormal portion with a nonuniform thickness in the liquid film of the composition 5 formed between the superstrate 11 and the substrate 1. Here, the controller 35 can specify the abnormal portion after it determines, based on image information obtained from the spread camera 26, that the composition 5 has spread over the entire area of the substrate 1.

After the abnormal portion is specified, the controller 35 causes a substrate stage 3 to position the substrate 1 in the X and Y directions such that the abnormal portion is arranged below the pressing member 50. In this state, the controller 35 lowers the pressing member 50 by the head 13 or the driving mechanism 51 to bring the pressing member 50 into contact with a part of the back surface 11b of the superstrate 11 corresponding to the abnormal portion, thereby pressing the part by the pressing member 50. FIG. 6C shows a state in which the press operation is performed using the pressing member 50.

As shown in FIGS. 5A and 5B, the planarization apparatus 100 may be provided with a force detector 53 (second detector) that detects the pressing force of the pressing member 50 against the superstrate 11. In this case, the controller 35 can control the press operation based on the detection result of the force detector 53 such that the pressing force of the pressing member 50 against the superstrate 11 reaches a target pressing force (the upper limit value of the pressing force). As in the first embodiment, the target pressing force can be decided to the pressing force corresponding to the target thickness of the liquid film of the composition 5 based on the relationship between the pressing force and the thickness of the liquid film of the composition 5 acquired in advance by experiment, simulation, or the like. Based on the detection result of the force detector 53, the controller 35 may also control the pressing speed and angle (inclination) of the pressing member 50 against the back surface 11b of the superstrate 11 in the press operation.

When the press operation ends, the controller 35 lifts the pressing member 50 by the head 13 or the driving mechanism 51 to separate the pressing member 50 from the superstrate 11. Then, the controller 35 positions the substrate 1 in the X and Y directions by the substrate stage 3 such that the liquid film of the composition 5 between the superstrate 11 and the substrate 1 is irradiated with light from a curing device 24. In this state, the curing device 24 emits light and the liquid film of the composition 5 is irradiated with the light via the superstrate 11, thereby curing the composition 5 between the superstrate 11 and the substrate 1.

After the composition 5 is cured, the controller 35 causes the head 13 to lower the holding member 12, thereby bringing the holding member 12 into contact with the superstrate 11 and causing the holding member 12 to hold the superstrate 11. Then, the controller 35 causes the head 13 to lift the holding member 12, thereby separating the superstrate 11 held by the holding member 12 from the cured composition 5. Thus, a planarized film (planarized layer) made of the cured product of the composition 5 can be formed in the entire area of the substrate 1.

As has been described above, the planarization apparatus 100 of this embodiment includes the pressing member 50, and performs the press operation using the pressing member 50. According to this embodiment, as in the first embodiment, the liquid film of the composition 5 having a uniform thickness can be formed between the superstrate 11 and the substrate 1. That is, a planarized film made of the cured product of the composition 5 having a uniform thickness can be formed on the substrate 1.

### Third Embodiment

The third embodiment according to the present invention will be described. In the first and second embodiments described above, a planarization apparatus has been exemplified as the shaping apparatus that shapes a composition on a substrate using a mold. In this embodiment, an imprint apparatus will be exemplified as the shaping apparatus. Note that this embodiment basically takes over the first embodiment, and matters not mentioned below can follow the first embodiment. In addition to or instead of the first embodiment, the second embodiment may be applied to this embodiment.

By curing a composition (imprint material) on a substrate while a mold with a concave-convex pattern formed therein is in contact with the composition, and separating the mold from the cured composition, the imprint apparatus can form, on the substrate, the cured product of the composition with the concave-convex pattern of the mold transferred thereto. Because the imprint apparatus requires a reasonable amount of time for the composition to fully fill the concave portion of the concave-convex pattern of the mold, the composition needs to be cured after waiting a predetermined time since the mold contacts the composition on the substrate. Hence, for the imprint apparatus, from the viewpoint of productivity, so-called multi-area imprint has been proposed, which collectively (simultaneously) transfers the pattern of the mold to two or more shot regions of a plurality of shot regions of the substrate. For multi-area imprint, a countermeasure to reduce defects (such as unfilled defects or abnormal Residual Layer Thickness (RLT)) of the pattern caused by the shape of the concave and convex (undulation) of the substrate itself is demanded.

Next, the arrangement and process of the imprint apparatus will be described. The arrangement of the imprint apparatus is basically similar to the arrangement of the planarization apparatus 100 described in the first embodiment. Therefore, a description will be given while replacing the planarization apparatus 100 shown in FIG. 1 with the imprint apparatus, and using the reference numerals of the components of the apparatus. Note that, while the planarization apparatus 100 uses a mold (superstrate) having a flat surface, the imprint apparatus uses a mold formed with a fine concave-convex pattern.

An imprint apparatus 100 uses a mold 11 formed with a concave-convex pattern, and transfers the concave-convex pattern of the mold 11 to a composition 5 supplied onto a substrate 1. The mold 11 is formed with the fine concave-convex pattern in a shaping surface 11a which faces the substrate 1. The mold 11 is a light transmissive member such as silica glass. The concave-convex pattern formed in the shaping surface 11a of the mold 11 has a layout based on the layout of two or more shot regions (the shapes, number, and arrangement of shot regions) on which multi imprinting is performed among a plurality of shot regions of the substrate 1. That is, the concave-convex pattern to be transferred collectively to the two or more shot regions is formed in the shaping surface 11a of the mold 11.

Next, an imprint process of this embodiment will be described. A controller 35 causes a supply device 20 to supply the composition 5 as a plurality of droplets onto all shot regions of the substrate 1, and then moves the substrate 1 to an imprint position by a substrate stage 3. The imprint position may be understood as a position below the mold 11 held by a holding member 12. After movement of the substrate 1 is completed, the controller 35 causes a head 13 to lower the mold 11 to bring the shaping surface 11a of the mold 11 into contact with the composition 5 on the substrate 1, and then releases holding of the mold 11 by the holding member 12. At the same time, the controller 35 starts observation of the contact state and the connection state of the droplets of the composition 5 by a spread camera 26. Based on image information obtained by the spread camera 26, the controller 35 performs the press operation if an abnormal portion with a nonuniform thickness in the liquid film of the composition 5 formed between the mold 11 and the substrate 1 is specified (detected). The press operation may be performed using the holding member 12 as described in the first embodiment, or may be performed using a pressing member 50 as described in the second embodiment.

When the press operation ends, the controller 35 lifts the holding member 12 or the pressing member 50 to separate the holding member 12 or the pressing member 50 from the mold 11. Then, the controller 35 positions the substrate 1 in the X and Y directions by the substrate stage 3 such that the liquid film of the composition 5 between the mold 11 and the substrate 1 is irradiated with light from the curing device 24. In this state, the curing device 24 emits light and the liquid film of the composition 5 is irradiated with the light via the mold 11, thereby curing the composition 5 between the mold 11 and the substrate 1.

After the composition 5 is cured, the controller 35 causes the head 13 to lower the holding member 12, thereby bringing the holding member 12 into contact with the mold 11 and causing the holding member 12 to hold the mold 11. Then, the controller 35 causes the head 13 to lift the holding member 12, thereby separating the mold 11 held by the holding member 12 from the cured composition 5. Thus, the pattern of the cured product of the composition 5 with the concave-convex pattern of the mold 11 transferred thereto can be formed on the substrate 1.

As has been described above, in this embodiment, a press operation is also performed in the imprint process. This can reduce defects (such as unfilling defects or abnormal residual layer thickness) of the pattern caused by the concave-convex shape of the substrate itself.

### Embodiment of Article Manufacturing Method

An article manufacturing method according to the embodiment of the present invention is suitable for manufacturing an article, for example, a microdevice such as a semiconductor device or a device having a microstructure.

The article manufacturing method according to this embodiment includes a shaping step of shaping a composition on a substrate using the above-described shaping apparatus and shaping method, a processing step of processing the substrate including the composition shaped in the shaping step, and a manufacturing step of manufacturing an article from the substrate processed in the processing step. The manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-215046 filed on Dec. 20, 2023, which is hereby incorporated by reference herein in its entirety.

What is claimed is:

1. A shaping apparatus comprising:
a film forming device including a holding member to hold a mold, and configured to form a composition between the mold and a substrate by performing a process of driving the holding member holding the mold to bring the mold into contact with the composition on the substrate and then releasing holding of the mold by the holding member; and
a curing device configured to cure the composition formed by the film forming device,
wherein, after the process, the film forming device performs a press operation of pressing the mold by a member that comes into partial contact with the mold.

2. The shaping apparatus according to claim 1, wherein the film forming device performs the press operation using the holding member as the member that comes into partial contact with the mold.

3. The shaping apparatus according to claim 2, wherein
the holding member is configured to hold an outer peripheral portion of the mold, and
the film forming device performs the press operation so as to press the outer peripheral portion of the mold by the holding member.

4. The shaping apparatus according to claim 1, wherein the member that comes into partial contact with the mold to perform the press operation is different from the holding member.

5. The shaping apparatus according to claim 1, wherein the member is configured to press the mold to reduce a nonuniform thickness of a liquid film that is formed between the mold and a substrate.

6. The shaping apparatus according to claim 5, further comprising a first detector configured to detect an abnormal portion with a nonuniform thickness in the liquid film,
wherein the film forming device performs the press operation to press a part of the mold corresponding to the abnormal portion detected by the first detector.

7. The shaping apparatus according to claim 5, further comprising a second detector configured to detect a pressing force against the mold in the press operation,
wherein the film forming device performs, based on a detection result of the second detector, the press operation so as to achieve a pressing force corresponding to a target thickness of the liquid film.

8. The shaping apparatus according to claim 1, wherein
the mold has a first surface to contact the composition on the substrate, and a second surface on an opposite side of the first surface, and
in the press operation, the film forming device presses the second surface of the mold by a member that comes into contact with the second surface of the mold.

9. The shaping apparatus according to claim 1, wherein the curing device cures the composition while the holding member is separated from the mold.

10. The shaping apparatus according to claim 1, wherein
the mold has a flat surface, and
the shaping apparatus is configured to planarize the composition on the substrate by bringing the flat surface of the mold into contact with the composition on the substrate.

11. A shaping method comprising:
forming a composition between a mold and a substrate by performing a process of driving a holding member holding the mold to bring the mold into contact with the composition on the substrate and then releasing holding of the mold by the holding member; and
curing the composition formed in the forming,
wherein the forming includes a press operation of, after the process, pressing the mold by a member that comes into partial contact with the mold.

12. An article manufacturing method comprising:
shaping a composition on a substrate using a shaping method defined in claim 11;
processing the substrate including the composition shaped in the shaping; and
manufacturing an article from the substrate processed in the processing.
